(19) United States
(12) Patent Application Publication
(10) Pub. No.: US 2022/0310868 A1
(43) Pub. Date: Sep. 29, 2022

(54) OPTICAL DEVICE

(71) Applicant: Panasonic Intellectual Property Management Co.,Ltd, Osaka (JP)

(72) Inventors: EIJI TAKEDA, Osaka (JP); SHINYA OKAMOTO, Kyoto (JP)

(21) Appl. No.: 17/805,471

(22) Filed: Jun. 6, 2022

Related U.S. Application Data
(63) Continuation of application No. PCT/JP2020/042355, filed on Nov. 13, 2020.

(30) Foreign Application Priority Data
Jan. 10, 2020 (JP) 2020-002653

(51) Int. Cl. H01L 31/108; H01L 31/0256; H01L 31/0224

(52) U.S. Cl. CPC H01L 31/108; H01L 31/0256; H01L 31/022408

(57) ABSTRACT

An optical device includes: a silicon substrate in which a plane direction of a crystal plane of a principal surface is a (111) plane, the principal surface having an uneven structure; and a conductor that is joined to the silicon substrate by Schottky junction, in which the conductor is directly joined to a (111) plane of at least one of a protruding portion or a depressed portion in the uneven structure.

### BACKGROUND

### 1. Technical Field

The present disclosure relates to an optical device.

### 2. Description of the Related Art

A photoelectric conversion technique using the Schottky junction, which is a junction between a metal and a semiconductor, is known in the related art. Particularly, a photoelectric conversion technique using surface plasmon resonance in the Schottky junction has been attracting attention.

As an example of an optical device using the photoelectric conversion technique, a Schottky type photodetection element that uses surface plasmon resonance in the Schottky junction (for example, Japanese Unexamined Patent Application Publication No. 2019-47016 (Patent Document 1)) has been proposed.

With this type of photodetection element, when light is absorbed, surface plasmon resonance brings free electrons of the metal temporarily into a high-energy state. The electrons that are brought temporarily into a high-energy state by surface plasmon resonance are called hot electrons (hot carriers). The hot electrons generated in the metal by the absorption of light are charge-separated by overcoming a Schottky barrier between the metal and the semiconductor and flow into the semiconductor side as a photocurrent.

### SUMMARY

One non-limiting and exemplary embodiment provides an optical device that can reduce a dark current by using a simple structure while implementing an increase in the light absorptance of surface plasmon resonance and controllability of the absorption wavelength.

In one general aspect, the techniques disclosed here feature an optical device, including: a silicon substrate in which a plane direction of a crystal plane of a principal surface is a (111) plane, the principal surface having an uneven structure; and a conductor that is joined to the silicon substrate by Schottky junction, in which the conductor is directly joined to a (111) plane of at least one of a protruding portion or a depressed portion in the uneven structure.

According to the present disclosure, it is possible to obtain an optical device that can reduce a dark current with a simple structure while implementing the increase in the light absorptance of the surface plasmon resonance and the controllability of an absorption wavelength.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 is a perspective view schematically illustrating a configuration of a part of an optical device according to an embodiment;

FIG. 2A is a plan view illustrating a configuration of a part of the optical device according to the embodiment;

FIG. 2B is a sectional view of the optical device according to the embodiment taken along line IIB-IIB in FIG. 2A;

FIG. 3 is a diagram schematically illustrating a surface state of an uneven structure in the optical device according to the embodiment;

FIGS. 4A and 4B are diagrams illustrating a surface state of a protruding portion in the uneven structure, when a silicon dioxide film is formed on the surface of the uneven structure of the silicon substrate and the silicon dioxide film is removed by hydrofluoric acid;

FIGS. 5A and 5B are diagrams illustrating a surface state of the protruding portion in the uneven structure when, after a silicon dioxide film is formed on the surface of the uneven structure of the silicon substrate and the silicon dioxide film is removed by hydrofluoric acid, cleaning treatment by an ammonium fluoride solution is performed;

FIG. 6 is a sectional view schematically illustrating another mode of the optical device according to the embodiment;

FIG. 7 is a sectional view illustrating a configuration of a part of an optical device according to a modification 1; and

FIG. 8 is a plan view illustrating a configuration of a part of an optical device according to a modification 2.

### DETAILED DESCRIPTIONS

### Underlying Knowledge Forming Basis of the Present Disclosure

First, prior to specific descriptions of embodiments of the present disclosure, the underlying knowledge forming the basis of the present disclosure is described.

A semiconductor photodetection element as a photodetection element using a semiconductor is known. The currently prevailing semiconductor photodetection element uses photoelectric conversion based on light absorption by an interband transition. For this reason, the semiconductor photodetection element cannot detect light having lower energy than the band gap energy of the semiconductor.

Taken into consideration, a photodetection element that is capable of photoelectric conversion in a wider wavelength region than previously known is desired. For example, if it is possible to detect light of a near-infrared region (hereinafter, described as “near-infrared light”), highly sensitive imaging may be possible at any hour of the day or night. For this reason, a photodetection element that can detect near-infrared light with high sensitivity is desired. Additionally, since near-infrared light is highly safe for the eyes, the photodetection element that detects near-infrared light is expected to be utilized in a sensor for autonomous driving of automobiles.

Regarding light in the visible region (hereinafter, described as “visible light”), a photodetection element using silicon (Si) has been widely available at a relatively low price. However, since near-infrared light has lower energy than visible light, near-infrared light cannot be detected without using a semiconductor having lower band gap energy.

On the other hand, a photodetection element using surface plasmon resonance in the Schottky junction, which is a junction between a metal and a semiconductor, has been proposed. This type of photodetection element can detect light of a wide wavelength region including long-wavelength light in the near-infrared region which has been difficult to use.

For the photodetection element using the Schottky junction, improved optical detection sensitivity of surface plasmon resonance has been desired. To address this, a technique of increasing the light absorptance of surface plasmon resonance has been considered.

Additionally, for the photodetection element using the Schottky junction, controllability of the absorption wavelength of light has also been demanded. That is, a photodetection element having a structure that can adjust a wavelength absorption region has been desired.

Given such circumstances, a photodetection element having an uneven structure in which protruding portions and depressed portions are formed periodically and repeatedly to achieve both an increase in the light absorptance of surface plasmon resonance and controllability of the absorption wavelength has been proposed. For example, as disclosed in Patent Document 1 described above, a photodetection element including a semiconductor layer having a periodic uneven structure in which protruding portions and depressed portions are formed periodically and repeatedly and a metal film formed on one surface side of the semiconductor layer to correspond with the periodic uneven structure has been proposed.

On the other hand, for a photodetection element using a Schottky junction, reducing the dark current due to a defect level in a Schottky interface has been desired. To address this, in the photodetection element disclosed in Patent Document 1, a cap structure using an insulation layer is employed to reduce the dark current. Specifically, in the photodetection element disclosed in Patent Document 1, to reduce the dark current, the insulation layer is formed between a top surface of the protruding portion in the periodic uneven structure of the semiconductor layer and the metal film, and thus a portion in which the Schottky junction is not formed between the metal film and the protruding portion of the semiconductor layer is included.

However, the photodetection element disclosed in Patent Document 1 has a complex device structure, and since a step of forming the insulation layer and a step of etching both the insulation layer and semiconductor layer are required for the photodetection element, the manufacturing process is also complex. Additionally, with the structure of the photodetection element disclosed in Patent Document 1, it is difficult to achieve Schottky interfaces that are all free of defects, and the reduction of dark current is limited.

As described above, with the conventional photodetection element, it has been difficult to reduce the dark current by using a simple structure while implementing the increase in the light absorptance of the surface plasmon resonance and the controllability of the absorption wavelength. That is, although (i) an increase in the light absorptance of the surface plasmon resonance, (ii) controllability of the absorption wavelength, and (iii) a reduction in dark current are important elements required for a highly sensitive photodetection element, it has been difficult in the conventional technique to implement an optical device that satisfies all of these elements with a simple structure.

In view of the above, the inventor of the present disclosure has given earnest consideration to such a problem and has thereby devised an optical device that can reduce dark current by using a simple structure while implementing an increase in the light absorptance of the surface plasmon resonance and the controllability of the absorption wavelength.

Specifically, the aspect of the optical device according to the present disclosure includes: a silicon substrate in which a plane direction of a crystal plane of a principal surface is a (111) plane, the principal surface having an uneven structure; and a conductor that is joined to the silicon substrate by Schottky junction, in which the conductor is directly joined to a (111) plane of at least one of a protruding portion or a depressed portion in the uneven structure.

According to the aspect of the present disclosure, since the principal surface of the silicon substrate has the uneven structure, it is possible to achieve both the increase in the light absorptance of the surface plasmon resonance and controllability of the absorption wavelength. In addition, since the plane direction of the crystal plane in the principal surface of the silicon substrate is the (111) plane, it is possible to enhance easily the flatness of the surface of the uneven structure in the silicon substrate. With this, it is possible to reduce the dark current due to the defect level in the Schottky interface between the uneven structure of the silicon substrate and the conductor. Therefore, it is possible to reduce the dark current with a simple structure without using a cap structure with an insulation layer like Patent Document 1.

Thus, according to the aspect of the optical device in the present disclosure, it is possible to reduce the dark current with a simple structure while implementing the increase in the light absorptance of the surface plasmon resonance and the controllability of the absorption wavelength. Therefore, it is possible to implement an optical device in a simple structure that has excellent controllability of the absorption wavelength and excellent photoelectric conversion efficiency.

In the aspect of the optical device according to the present disclosure, the (111) plane of the protruding portion may be a top surface of the protruding portion, and the (111) plane of the depressed portion may be a bottom surface of the depressed portion.

With this configuration, the top surface of the protruding portion or the bottom surface of the depressed portion is a flat surface; therefore, it is possible to achieve easily both the high photoelectric conversion efficiency and reduction in the dark current.

In the aspect of the optical device according to the present disclosure, the conductor may be directly joined to both the top surface of the protruding portion and the bottom surface of the depressed portion.

With this configuration, the conductor is joined to both the top surface of the protruding portion and bottom surface of the depressed portion; therefore, it is possible to achieve both the high photoelectric conversion efficiency and reduction in the dark current.

In the aspect of the optical device according to the present disclosure, a side surface of the protruding portion or a side surface of the depressed portion may have a portion with which the conductor is not in contact.

When the conductor is in contact with the side surface of the protruding portion and/or the side surface of the depressed portion, comparing with a case where the conductor is not in contact with the side surface of the protruding portion and/or the side surface of the depressed portion, the area of the Schottky interface is increased, but the light absorptance of the surface plasmon resonance is reduced. In addition, since the plane direction of the crystal plane in the side surface of the protruding portion and the side surface of the depressed portion is not the (111) plane, the side surface of the protruding portion and the side surface of the depressed portion are less flat than that of the top surface of the protruding portion and the bottom surface of the depressed portion. For this reason, when the conductor is in contact with the side surface of the protruding portion and/or the side surface of the depressed portion, the reduction in the dark current due to the defect level in the Schottky interface would rather be inhibited. Therefore, since there is a portion in which the conductor is not in contact with the side surface of the protruding portion or the side surface of the depressed portion, comparing with a case where the conductor is in contact with the entire side surface of the protruding portion or the entire side surface of the depressed portion, it is possible to suppress the reduction in the light absorptance and to improve the photoelectric conversion efficiency, and also it is possible to reduce the dark current by suppressing the defect level in the Schottky interface. In terms of the improvement of the photoelectric conversion efficiency and the reduction in the dark current, it is favorable for the conductor to be not in contact with the entire side surface of the protruding portion nor the entire side surface of the depressed portion.

In the aspect of the optical device according to the present disclosure, the uneven structure may have a characteristic of absorbing an electromagnetic wave through surface plasmon resonance.

With this configuration, it is possible to induce surface plasmon resonance when being irradiated with an electromagnetic wave such as light or the like.

In the aspect of the optical device according to the present disclosure, the conductor may be an elemental metal or an alloy containing at least one selected from gold, silver, copper, palladium, and aluminum.

With the conductor including any one of the above-described metals having excellent plasmonic characteristics, it is possible to generate hot electrons highly efficiently. That is, with use of the above metals, surface plasmon resonance is induced easily. With this, it is possible to improve the photoelectric conversion efficiency. In an alloy layer of the above metals, since it is possible to adjust a work function based on the alloy composition thereof, the conductor including an alloy layer can implement a low Schottky barrier that does not make ohmic contact with the silicon and can improve the efficiency of taking out a photocurrent. With this, it is possible to further improve the photoelectric conversion efficiency.

In the aspect of the optical device according to the present disclosure, the conductor may be an oxide containing at least one selected from indium, tin, zinc, and cadmium.

In this case, the conductor is, for example, at least one conductive oxide selected from tin doped indium oxide (ITO), aluminum doped zinc oxide (AZO), gallium doped zinc oxide (GZO), and cadmium oxide (CdO). With use of the conductor made of such material, the plasmon absorption efficiency in a region of longer wavelength such as a near-infrared region and the transportation efficiency of the hot electrons are enhanced. With this, it is possible to further improve the photoelectric conversion efficiency.

In the aspect of the optical device according to the present disclosure, the conductor may be a nitride containing at least one selected from titanium, zirconium, hafnium, vanadium, niobium, tantalum, molybdenum, and tungsten.

In this case, the conductor is, for example, at least one metal nitride selected from titanium nitride (TiN), zirconium nitride (ZrN), tantalum nitride (TaN), hafnium nitride (HfN), vanadium nitride (VN), niobium nitride (NbN), molybdenum nitride (MoN), and tungsten nitride (WN). With use of the conductor made of such material, it is possible to enhance the plasmon absorption efficiency in a wavelength region from a long wavelength region in a visible region to a near-infrared region. With this, it is possible to further improve the photoelectric conversion efficiency.

In the aspect of the optical device according to the present disclosure, the conductor may be a laminated structure including at least two selected from the metal or the alloy, the oxide, and the nitride.

With this configuration, the light absorption occurs easily; therefore, it is possible to further increase the light absorptance and also to reduce the Schottky barrier. With this, it is possible to further improve the photoelectric conversion efficiency.

In the aspect of the optical device according to the present disclosure, the optical device may further include an electrode layer that covers the protruding portion, the depressed portion, and the conductor.

According to this configuration, it is possible to take out easily by the electrode layer a current that is photoelectric-converted by receiving light.

Hereinafter, specific embodiments of the present disclosure are described with reference to the drawings. The embodiments described below all illustrate a comprehensive or specific example of the present disclosure. Therefore, numerical values, shapes, materials, constituents, arrangement positions and connection conditions of constituents, steps and the order of steps, and so on, which are mentioned in the following embodiments, are merely an example and are not intended to limit the present disclosure. Accordingly, of the constituents in the embodiments, a constituent that is not described in an independent claim is described as an optional constituent.

The drawings are schematic diagrams and are not necessarily strict illustrations. Therefore, the scale and the like in the drawings are not necessarily consistent. In the drawings, the same reference numerals are assigned to substantially the same configurations, and duplicated descriptions are omitted or simplified.

### Embodiment

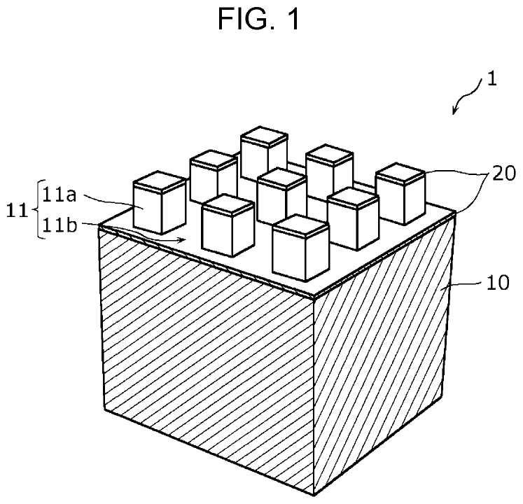

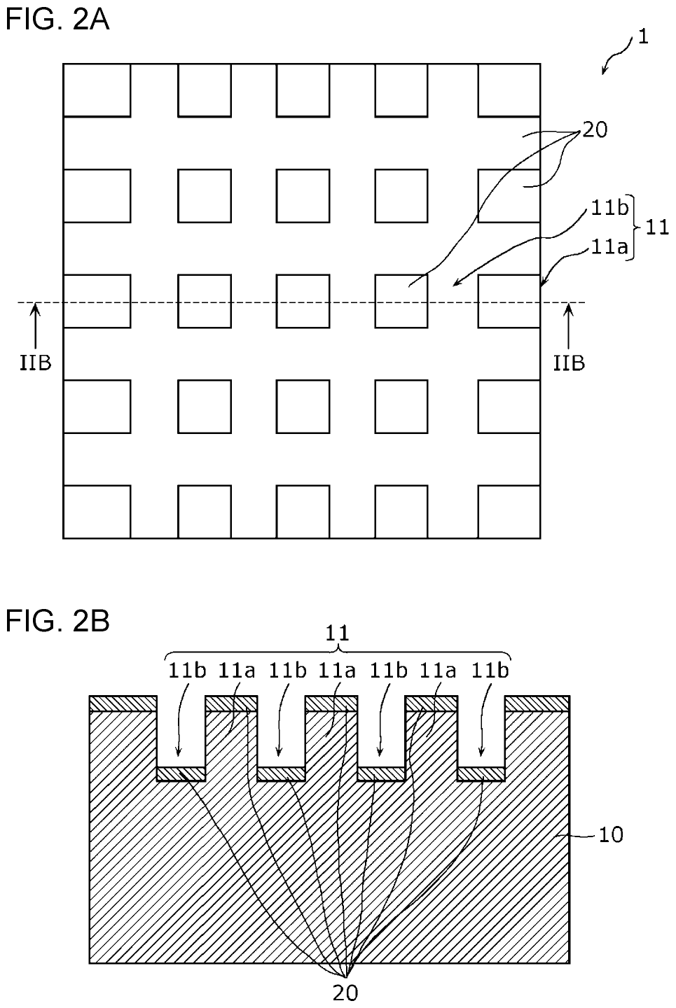

First, a configuration of an optical device 1 according to an embodiment is described with reference to FIGS. 1, 2A, and 2B. FIG. 1 is a perspective view schematically illustrating a configuration of a part of the optical device 1 according to the embodiment. FIG. 2A is a plan view illustrating a configuration of a part of the optical device 1. FIG. 2B is a sectional view of the optical device 1 taken along line IIB-IIB in FIG. 2A.

As illustrated in FIGS. 1, 2A, and 2B, the optical device 1 includes a silicon substrate 10 and a conductor 20.

For example, the silicon substrate 10 is an n-type or a p-type semiconductor substrate and functions as a semiconductor in the optical device 1. In this embodiment, the silicon substrate 10 is an n-type semiconductor substrate. The silicon substrate 10 is a Si (111) substrate in which the plane direction of a crystal plane of a principal surface is the (111) plane.

As illustrated in FIG. 1, a principal surface of the silicon substrate 10 has an uneven structure 11. That is, the uneven structure 11 is a part of the silicon substrate 10. It is possible to form the uneven structure 11 by processing the (111) plane as the principal surface of the silicon substrate 10 into an uneven form.

The uneven structure 11 is a fine structure having a configuration in which at least either of multiple protruding portions and multiple depressed portions in a nanometer-order size are arrayed periodically and repeatedly. The multiple protruding portions and/or the multiple depressed portions included in the uneven structure 11 are formed on the principal surface (that is, the (111) plane) of the silicon substrate 10. The multiple protruding portions and/or the multiple depressed portions included in the uneven structure 11 are formed repeatedly in directions parallel to the principal surface of the silicon substrate 10.

As illustrated in FIGS. 1, 2A, and 2B, the uneven structure 11 in this embodiment includes multiple protruding portions 11a. Specifically, the uneven structure 11 includes the multiple protruding portions 11a formed periodically in each direction of two axes that are orthogonal to each other and parallel to the principal surface of the silicon substrate 10. That is, as illustrated in FIG. 2A, when viewed from above, the multiple protruding portions 11a are arrayed in the form of a matrix. The uneven structure 11 including the multiple protruding portions 11a as described above can be created by forming depressed portions 11b as trenches on the principal surface of the silicon substrate 10 by etching or the like. Thus, the uneven structure 11 includes the multiple protruding portions 11a arrayed periodically and the depressed portions 11b as portions between two adjacent protruding portions 11a. In this case, as illustrated in FIGS. 1 and 2A, the depressed portions 11b in this embodiment are not separated and seamless; however, the depressed portions 11b may be separated into multiple pieces. Since the multiple protruding portions 11a are arrayed periodically, as illustrated in FIG. 2B, in a section of the optical device 1, two adjacent depressed portions 11b are also arrayed periodically.

Thus, one principal surface of the silicon substrate 10, which is a Si (111) substrate, has the uneven structure 11 as a trench structure or a texture structure including the protruding portions 11a and the depressed portions 11b.

Each of the multiple protruding portions 11a is a pillared body made of silicon (a Si pillar). For example, the shape of each of the multiple protruding portions 11a is a quadrangular pillar. For instance, the shape of each protruding portion 11a viewed from above is a square pillar. In this embodiment, all of the protruding portions 11a have the same shape and the same size; however, the configuration is not limited thereto.

Each protruding portion 11a has, for example, a height and width of greater than or equal to 10 nm and less than 1000 nm and an aspect ratio (height/width) of about 0.5 to 2. In other words, each depressed portion 11b has a depth and width of greater than or equal to 10 nm and less than 1000 nm and an aspect ratio (depth/width) of about 0.5 to 2. That is, the depressed portion 11b is not a deep trench structure but is a shallow trench structure. The aspect ratio between the protruding portion 11a and the depressed portion 11b is preferably less than 1.0. That is, the protruding portion 11a and the depressed portion 11b preferably have a shape with a greater width than height. The center-to-center distance between two adjacent protruding portions 11a or two adjacent depressed portions 11b is preferably greater than or equal to 10 nm and less than 1000 nm. The size of the protruding portion 11a and the depressed portion 11b is not limited to the above numerical range.

Since the uneven structure 11 is formed on the (111) plane, which is the principal surface of the silicon substrate 10, the protruding portion 11a and the depressed portion 11b are also formed on the (111) plane of the silicon substrate 10. Specifically, a top surface of the protruding portion 11a and a bottom surface of the depressed portion 11b are the (111) plane of the silicon substrate 10.

The conductor 20 is joined to the silicon substrate 10 by Schottky junction. The conductor 20 may be joined to at least a part of the silicon substrate 10 by Schottky junction. Specifically, the conductor 20 is joined by Schottky junction to the uneven structure 11 included in the silicon substrate 10. The uneven structure 11 joined to the conductor 20 by Schottky junction has a characteristic of absorbing an electromagnetic wave through surface plasmon resonance. For example, the uneven structure 11 absorbs light by inducing surface plasmon resonance when the uneven structure 11 is irradiated with light as an electromagnetic wave.

The conductor 20 is directly joined to the (111) plane of at least one of the protruding portion 11a and the depressed portion 11b in the uneven structure 11. In this embodiment, the conductor 20 is directly joined to both the (111) plane of the protruding portion 11a and the (111) plane of the depressed portion 11b. Specifically, the (111) plane of the protruding portion 11a is the top surface of the protruding portion 11a, and the (111) plane of the depressed portion 11b is the bottom surface of the depressed portion 11b. Accordingly, the conductor 20 is directly joined to both the top surface of the protruding portion 11a and the bottom surface of the depressed portion 11b.

The conductor 20 is formed on the top surface of each of the multiple protruding portions 11a. That is, the conductor 20 formed on the top surface of the protruding portion 11a is formed while being separated into multiple pieces for each protruding portion 11a. The conductor 20 is formed on the entire top surface of each of the protruding portions 11a. That is, the top surface of each protruding portion 11a is covered with the conductor 20. The conductor 20 formed on the bottom surface of the depressed portion 11b is formed on the entire bottom surface of each of the depressed portions 11b in the uneven structure 11.

In this embodiment, a portion of a side surface of the protruding portion 11a is not in contact with the conductor 20. Specifically, the conductor 20 is not formed on the entire side surface of the protruding portion 11a nor on the entire side surface of the depressed portion 11b, and the entire side surface of the protruding portion 11a and the entire side surface of the depressed portion 11b are exposed. The side surface of the protruding portion 11a is an outer wall surface positioned in a lateral direction of the protruding portion 11a, and the side surface of the depressed portion 11b is an inner wall surface positioned in a lateral direction of the depressed portion 11b. In this embodiment, the side surface of the protruding portion 11a and the side surface of the depressed portion 11b are the same. Thus, the side surface of the depressed portion 11b also includes a portion with which the conductor 20 is not in contact.

The conductor 20 is, for example, a thin conductive film having a thickness of a nanometer-order size. The thickness of the conductor 20 is less than the height of the protruding portion 11a or the depth of the depressed portion 11b. The film thickness of the conductor 20 may be, for instance, less than or equal to 100 nm, less than or equal to 50 nm, or otherwise less than or equal to 20 nm. The film thickness of the conductor 20 is constant across the entirety of the optical device 1 but is not limited to being constant.

For the conductor 20, an optimal material is selected in accordance with the wavelength of the incident electromagnetic wave, the device structure, and the like to induce surface plasmon resonance with high efficiency. A metal, for example, can be used as the material of the conductor 20.

Specifically, the conductor 20 is an elemental metal selected from gold (Au), silver (Ag), copper (Cu), palladium (Pd), and aluminum (Al) or an alloy containing at least one of the above metals. In this embodiment, the conductor 20 is an alloy film formed of Au and Ag (a AuAg alloy film).

The conductor 20 may be an intermetallic compound or a solid solution alloy containing at least two metals. Here, “intermetallic compound” denotes a compound in which two or more metals are bonded at a simple integral ratio; that is, an alloy in which atoms are arrayed regularly and orderly over a relatively great distance (for example, greater than or equal to 1 nm). Here, “solid solution alloy” denotes a single-phase alloy in which multiple metal elements are distributed uniformly and disorderly within a crystal, which has a structure in which the structure of any one of the metals is held while another metal invades or substitutes.

Whether a substance is an alloy can be confirmed by, for example, element mapping using scanning transmission electron microscopy (STEM). It is possible to determine that a substance is an alloy if the substance is not separated into phases of multiple metal elements that are the constituents of the substance. More specifically, for example, if the following conditions (1) and (2) are satisfied, it can be determined that the conductor 20 is an alloy of a first metal and a second metal.

(1) When element mapping measurement is performed by using STEM with a resolution of 1 nm×1 nm, the first metal and the second metal are detected in a region of greater than or equal to 80% of the entire region occupied by the conductor 20.
(2) With energy dispersive X-ray (EDX) spectroscopy and line analysis, the first metal and the second metal are detected at a ratio reflecting the composition ratio also in a section of the layer.

Whether a substance is a solid solution alloy can be confirmed based on, for example, a diffraction pattern obtained by an X-ray diffraction method. In the diffraction pattern, if a peak shift from the peak position of each of the first metal only and the second metal only is observed by reflecting the composition ratio in accordance with Vegard's law, it is possible to determine that the conductor 20 is a solid solution alloy of the first metal and the second metal.

On the other hand, whether the conductor 20 is an intermetallic compound can be confirmed by, for example, an electron diffraction method or an X-ray diffraction method. If the diffraction pattern obtained by an electron diffraction method or an X-ray diffraction method matches the diffraction pattern of an intermetallic compound of the first metal and the second metal disclosed in literature such as a specialized book, it is possible to determine that the conductor 20 is an intermetallic compound of the first metal and the second metal.

When the composition ratio of the intermetallic compound is different from the composition ratio disclosed in the literature, in some cases, a small deviation in intervals of diffraction spots (peaks in the case of X-ray diffraction) in accordance with deviation of plane intervals may be seen. In this case, lattice intervals are obtained from a lattice image obtained by structural analysis of particles using STEM, and whether the intermetallic compound is contained may be determined based on whether the peak position calculated from the lattice intervals matches the peak position disclosed in the literature. Otherwise, the composition ratio of particles may be obtained by EDX spectroscopy to calculate the lattice intervals in accordance with Vegard's law, and whether the intermetallic compound is contained may be determined based on whether the peak position calculated from the lattice intervals matches the peak position disclosed in the literature.

The conductor 20 may be an oxide containing at least one selected from indium (In), tin (Sn), zinc (Zn), and cadmium (Cd).

The conductor 20 may be a nitride containing at least one selected from titanium (Ti), zirconium (Zr), hafnium (Hf), vanadium (V), niobium (Nb), tantalum (Ta), molybdenum (Mo), and tungsten (W).

Otherwise, the conductor 20 may be a laminated structure including at least two selected from (i) an elemental metal selected from gold, silver, copper, palladium, and aluminum or an alloy containing at least one of the above metals, (ii) an oxide containing at least one selected from indium, tin, zinc, and cadmium, or (iii) a nitride containing at least one selected from titanium, zirconium, hafnium, vanadium, niobium, tantalum, molybdenum, and tungsten. That is, the conductor 20 may be a laminated film formed of multiple layers.

The optical device 1 formed as described above can be used as the photodetection element that performs photoelectric conversion in response to being irradiated with light. In the optical device 1 in this embodiment, the photoelectric conversion function is implemented by taking out as a current hot electrons that are induced by surface plasmon resonance when irradiated with light. For example, once light enters the optical device 1, the light is absorbed highly efficiently by the conductor 20 as a result of surface plasmon resonance, and the hot electrons are induced into the conductor 20. The hot electrons induced into the conductor 20 are photoelectrically converted by the Schottky junction between the conductor 20 and the silicon substrate 10. Specifically, the hot electrons induced into the conductor 20 are charge-separated by overcoming the Schottky barrier between the conductor 20 and the protruding portion 11a and the depressed portion 11b in the uneven structure 11 of the silicon substrate 10 and flow into the silicon substrate 10 side as a photocurrent.

With the optical device 1 having the configuration illustrated in FIG. 1, the light absorptance is enhanced due to the surface plasmon resonance of the nano-antenna structure; therefore, it is possible to improve the photoelectric conversion efficiency. For example, with the optical device 1 in this embodiment, it is possible to improve the light absorptance of near-infrared light to about 90%.

Since the optical device 1 in this embodiment includes the uneven structure 11, it is possible to control the wavelength region of the electromagnetic wave that induces surface plasmon resonance. For example, it is possible to control the wavelength region of the light entering the optical device 1 by adjusting the shape and size of each of the protruding portion 11a and the depressed portion 11b in the uneven structure 11. Specifically, it is possible to shift the absorption peak wavelength of the light entering the optical device 1 by adjusting the width or height of each protruding portion 11a (the Si pillar), the cycle of the protruding portions 11a, and the film thickness of the conductor 20 adjusted, or by adjusting the width or depth of each depressed portion 11b, the cycle of the depressed portions 11b, and the film thickness of the conductor 20. In this case, it is possible to shift the absorption peak wavelength to a long wavelength side by adjusting the width of each of the protruding portion 11a and the depressed portion 11b. For instance, in a case where a AuAg alloy film (film thickness of 15 nm, for example) is used as the conductor 20, it is possible to set the absorption peak wavelength of the optical device 1 to 1310 nm or to 1550 nm by adjusting the width, height, and cycle of the protruding portions 11a. Thus, according to the optical device 1 in this embodiment, it is possible to design a unique structure optimized for surface plasmon resonance. With this, it is possible to achieve both an improvement in the light absorptance and an improvement in the sensitivity by reducing the Schottky barrier.

Next, a method of manufacturing the optical device 1 according to this embodiment is described.

First, the silicon substrate 10 including the uneven structure 11 is created. The silicon substrate 10 including the uneven structure 11 can be created by, for example, using a patterning technique such as electron beam lithography or the like.

For example, as the silicon substrate 10, a Si (111) substrate is prepared in which the plane direction of a crystal plane of the principal surface is the (111) plane. A positive resist is applied to the principal surface of the silicon substrate 10 by a spin coating method or the like, a desired portion is irradiated with an electron beam, and thereafter development processing is performed to remove the resist in the portion irradiated with the electron beam. Only a portion from which the resist is removed within the principal surface of the silicon substrate 10 is etched by using on this silicon substrate 10 the reactive ion etching technique or the like using etching gas such as SF₆ gas. With this, it is possible to form the uneven structure 11 including the protruding portion 11a and the depressed portion 11b on the principal surface of the silicon substrate 10.

Next, treatment for cleaning up the surface (the exposed surface) of the uneven structure 11 of the silicon substrate 10 that is exposed by the etching to reduce a defect of the surface of the silicon substrate 10 is performed.

For example, for the silicon substrate 10 on which the uneven structure 11 is formed, for example, contamination of the surface of the silicon substrate 10 is removed by a piranha solution or the like, and thereafter cleaning treatment for the surface of the uneven structure 11 of the silicon substrate 10 is performed by an ammonium fluoride solution (NH₄F aqueous solution).

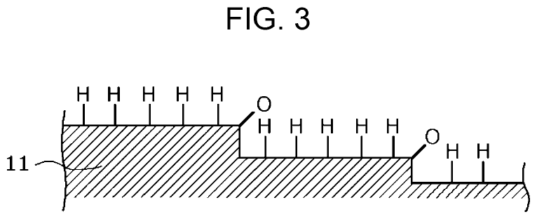

With this, as illustrated in FIG. 3, it is possible to form the surface of the uneven structure 11 into a step-terrace structure of the height of angstrom size (that is, at the atomic level). This makes it possible to flatten the (111) plane of the silicon substrate 10 in the uneven structure 11 at the atomic level. FIG. 3 is a diagram schematically illustrating a section of a part of the top surface of the protruding portion 11a or the bottom surface of the depressed portion 11b in the uneven structure 11 viewed at the atomic level. As illustrated in FIG. 3, with the cleaning treatment performed, the surface of the uneven structure 11 of the silicon substrate 10 obtains the step-terrace structure including a terrace, which is a complete flat surface at the atomic level, and a step, which is a stepped portion.

The ammonium fluoride solution used for the cleaning treatment may be deoxygenated. A treatment agent used for the cleaning treatment is not limited to the ammonium fluoride solution. The cleaning treatment may be performed by using deoxygenated ultrapure water instead of the ammonium fluoride solution.

As described above, use of the Si (111) substrate as the silicon substrate 10 makes it possible to form the surface of the uneven structure 11 of the silicon substrate 10 into the step-terrace structure. Specifically, it is possible to form the top surface of the protruding portion 11a and the bottom surface of the depressed portion 11b, which are the (111) plane of the uneven structure 11, into the step-terrace structure and form it into a flat surface at the atomic level.

In addition, with the cleaning treatment for the surface of the uneven structure 11 of the silicon substrate 10 performed, as illustrated in FIG. 3, it is possible to hydrogen-terminate an unbound bond of the silicon in the surface (that is, the top surface of the protruding portion 11a, the bottom surface of the depressed portion 11b) of the terrace of the uneven structure 11 in the step-terrace structure. An atom other than hydrogen such as oxygen may be adsorbed onto the step of the step-terrace structure; however, it is favorable for the step to be hydrogen-terminated as well.

Accordingly, with the cleaning treatment performed for cleaning of the surface of the silicon substrate 10, which is the Si (111) substrate on which the uneven structure 11 is formed, it is possible to form the top surface of the protruding portion 11a and the bottom surface of the depressed portion 11b in the uneven structure 11 into a flat surface that is flattened at the atomic level and hydrogen-terminated.

In this embodiment, the step of the cleaning treatment by the ammonium fluoride solution is performed after the uneven structure 11 is formed on the silicon substrate 10; however, it is favorable to perform a step of forming a dioxide film on the surface of the silicon substrate 10 and a step of removing the dioxide film before the step of the cleaning treatment. Specifically, after the uneven structure 11 is formed on the silicon substrate 10, the surface of the silicon substrate 10 is oxidized by annealing treatment or strong acid treatment to form a silicon dioxide film intentionally, the silicon dioxide film is then removed by hydrofluoric acid (HF), and thereafter the cleaning treatment is performed by the ammonium fluoride solution. With this, since a silicon dioxide film of a uniform film thickness is formed on the surface of the uneven structure 11, it is possible to form the entire surface of the uneven structure 11 into a uniform step-terrace structure by removing the silicon dioxide film. Therefore, it is possible to further reduce a defect of the surface of the uneven structure 11. When the silicon dioxide film is removed by the hydrofluoric acid (HF), a silicon surface layer under the silicon dioxide film may be removed with the silicon dioxide film by intentional over-etching. With this, it is possible to form the entire surface of the (111) plane of the exposed uneven structure 11 into a uniform step-terrace structure.

Next, after the cleaning treatment of the silicon substrate 10 is performed, the conductor 20 is formed. For example, the conductor 20 in the form of a film can be formed by a spattering method, a vacuum evaporation method, or the like. With this, it is possible to manufacture the optical device 1 having the structure illustrated in FIGS. 1, 2A, and 2B. When the conductor 20 in the form of a film is formed, the conductor 20 may be formed also on a part of the side surface of the protruding portion 11a (or the side surface of the depressed portion 11b).

In the optical device 1 manufactured as described above, since the cleaning treatment of the silicon substrate 10 is performed, it is possible to form the top surface of the protruding portion 11a and the bottom surface of the depressed portion 11b in the uneven structure 11 into a flat surface that is flattened at the atomic level and hydrogen-terminated. With this, it is possible to reduce greatly a defect of the surface of the uneven structure 11 in the silicon substrate 10. Therefore, it is possible to suppress the formation of an oxide layer on an interface between the silicon of the uneven structure 11 and the conductor 20 and to directly join the uneven structure 11 to the conductor 20 in a defect-less manner.

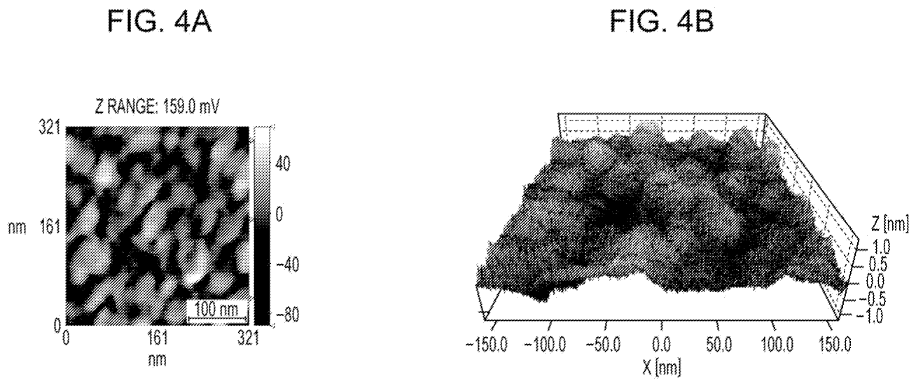

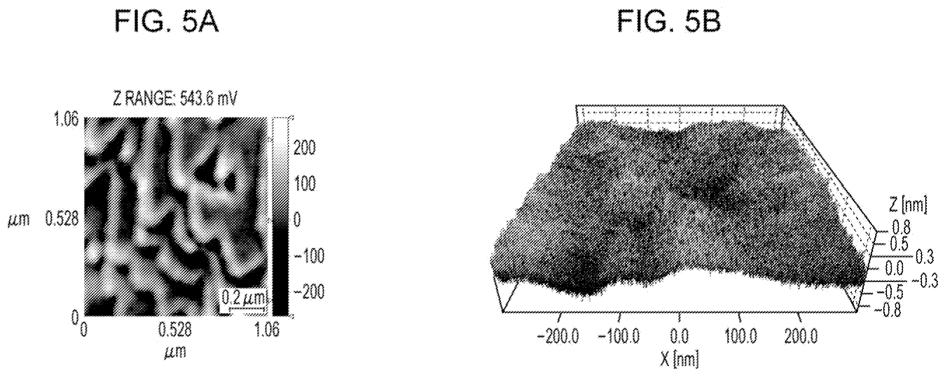

Here, an effect of the cleaning treatment for the surface of the uneven structure 11 is described with reference to FIGS. 4A to 5B. FIGS. 4A and 4B illustrate a surface state of the protruding portion 11a in the uneven structure 11 in a case where the silicon dioxide film is formed on the surface of the uneven structure 11, and the silicon dioxide film is removed by the hydrofluoric acid. FIGS. 5A and 5B illustrate a surface state of the protruding portion 11a in the uneven structure 11 in a case where the silicon dioxide film is formed on the surface of the uneven structure 11, and after the silicon dioxide film is removed by the hydrofluoric acid, the cleaning treatment by the ammonium fluoride solution is further performed. That is, FIGS. 4A and 4B illustrate a case where the cleaning treatment of the uneven structure 11 by the ammonium fluoride solution is not performed, and FIGS. 5A and 5B illustrate a case where the cleaning treatment of the uneven structure 11 by the ammonium fluoride solution is performed. FIGS. 4A to 5B are images of an atomic force microscope. In FIGS. 4A to 5B, FIGS. 4A and 5A illustrate two-dimensionally a part of the top surface of the protruding portion 11a, and FIGS. 4B and 5B illustrates three-dimensionally a part of the top surface of the protruding portion 11a.

As illustrated in FIGS. 4A and 4B, when the cleaning treatment of the uneven structure 11 by the ammonium fluoride solution is not performed, the surface of the uneven structure 11 is flattened but is not flattened at the atomic level. As illustrated in FIGS. 4A and 4B, when the cleaning treatment is not performed, no step-terrace structure is observed.

On the other hand, as illustrated in FIGS. 5A and 5B, when the cleaning treatment of the uneven structure 11 by the ammonium fluoride solution is performed, the step-terrace structure is observed in the surface of the uneven structure 11, and it can be seen that the silicon surface of the uneven structure 11 is a substantially flat surface at the atomic level. In such a state, the surface of the uneven structure 11 is in a defect-free state. Additionally, it can be also seen that the surface of the uneven structure 11 having the step-terrace structure is hydrogen-terminated.

In the optical device 1 in this embodiment, as long as a defect on the surface of the top surface of the protruding portion 11a and the bottom surface of the depressed portion 11b in the uneven structure 11 is reduced, the state as illustrated in FIGS. 5A and 5B where the step-terrace structure can be clearly confirmed is not necessarily required. That is, even when the cleaning treatment is not performed as illustrated in FIGS. 4A and 4B, it is possible to flatten the surface of the uneven structure 11 by using the Si (111) substrate as the silicon substrate 10 more than a case where a Si (100) substrate or a Si (110) substrate is used as the silicon substrate 10. Whether the surface of the silicon substrate 10 is hydrogen-terminated can be determined by, for example, a Fourier transform infrared spectroscopy method (FT-IR). Additionally, use of the FT-IR analyzing an infrared light absorption peak, which is caused by Si—H bonding or Si—H₂ bonding, allows for identification of the Si—H bonding state or the Si—H₂ bonding state, and it is possible to use the identified state as an index for the flatness, defect state, or the like of the surface of the silicon substrate 10.

As described above, according to the optical device 1 in this embodiment, since the principal surface of the silicon substrate 10 has the uneven structure 11, it is possible to achieve both the increase in the light absorptance of the surface plasmon resonance and controllability of the absorption wavelength.

In addition, since the plane direction of the crystal plane in the principal surface of the silicon substrate 10 is the (111) plane, it is possible to easily enhance the flatness of the surface of the uneven structure 11 in the silicon substrate 10. Specifically, it is possible to form the top surface of the protruding portion 11a and the bottom surface of the depressed portion 11b in the uneven structure 11 into a flat surface at the atomic level. Consequently, it is possible to reduce a defect of each of the top surface of the protruding portion 11a and the bottom surface of the depressed portion 11b. With this, it is possible to directly join the protruding portion 11a and the depressed portion 11b to the conductor 20 with less defect. Therefore, it is possible to reduce the dark current due to the defect level in the Schottky interface between the uneven structure 11 of the silicon substrate 10 and the conductor 20.

As described above, according to the optical device 1 in this embodiment, it is possible to reduce the dark current with a simple structure while implementing the increase in the light absorptance of the surface plasmon resonance and the controllability of the absorption wavelength. Therefore, it is possible to implement the optical device 1 in a simple structure that has excellent controllability of the absorption wavelength and excellent photoelectric conversion efficiency.

The current taken out by the photoelectric conversion in the optical device 1 can be taken out by using a first electrode layer 31 and a second electrode layer 32 as illustrated in an optical device 1A in FIG. 6. The optical device 1A illustrated in FIG. 6 has a configuration including the first electrode layer 31 and the second electrode layer 32 in addition to the configuration of the optical device 1 described above. The first electrode layer 31 and the second electrode layer 32 are electrically connected to each other via an electric wire 40.

The first electrode layer 31 covers the protruding portion 11a, the depressed portion 11b, and the conductor 20. Specifically, the first electrode layer 31 covers the conductor 20 and the entire exposed surface of the uneven structure 11. Thus, the first electrode layer 31 is formed on the top surface of each protruding portion 11a so as to bridge over the conductor 20 separated into multiple pieces. That is, the first electrode layer 31 is in contact with each of the multiple conductors 20 separated from each other because of the uneven structure 11.

The first electrode layer 31 is an ohmic electrode layer. Therefore, a portion in which the first electrode layer 31 and the conductor 20 are in contact with each other is in ohmic contact. A portion in which the first electrode layer 31 and the silicon substrate 10 are in contact with each other is also in ohmic contact. Specifically, a portion in which the first electrode layer 31 and the side surface of the protruding portion 11a (or the side surface of the depressed portion 11b) are in contact with each other is in ohmic contact.

As long as the first electrode layer 31 is a material having the ohmic characteristics with respect to the conductor 20, any material may be used. However, when the first electrode layer 31 in FIG. 6 is formed on a side of the optical device 1A on which the electromagnetic wave enters, it is favorable for the material to have the transmission characteristics with respect to the wavelength of the electromagnetic wave. For example, in a case where the optical device 1A absorbs visible light or infrared light, it is possible to use a transparent conductive film formed of indium tin oxide (ITO) or the like as the first electrode layer 31.

The second electrode layer 32 is formed on a principal surface that is opposite to the principal surface on which the uneven structure 11 of the silicon substrate 10 is formed. Specifically, assuming that the principal surface on which the uneven structure 11 of the silicon substrate 10 is formed is a first principal surface, the second electrode layer 32 is formed on a second principal surface opposite to the first principal surface. For example, the second electrode layer 32 may be formed on the entirety of the second principal surface of the silicon substrate 10 or may be formed on a part of the second principal surface.

The second electrode layer 32 is an ohmic electrode layer. Therefore, a portion in which the second electrode layer 32 and the silicon substrate 10 are in contact with each other is in ohmic contact. As long as the second electrode layer 32 is a material having the ohmic characteristics with respect to the silicon substrate 10, any material may be used.

In the optical device 1A formed as described above, with the optical device 1A irradiated with light emitted from an light source 2, the hot electrons induced by surface plasmon resonance are photoelectrically converted by the Schottky junction between the conductor 20 and the silicon substrate 10, and a current flows, as with the optical device 1 described above. The current generated in the optical device 1A can be taken out to the outside of the optical device 1A by the first electrode layer 31 and the second electrode layer 32 connected with each other via the electric wire 40. That is, once the optical device 1A is irradiated with the light from the light source 2, a current flows through the optical device 1A via the electric wire 40.

In FIG. 6, the light source 2 is arranged on a side on which the conductor 20 of the silicon substrate 10 is formed (the first principal surface side). Specifically, the light source 2 is arranged on the first electrode layer 31 side of the optical device 1. Thus, the light source 2 emits the light toward the first electrode layer 31 of the optical device 1A. The light source 2 is, for instance, a solid light-emitting light source using a semiconductor light-emitting element such as a laser diode or a light-emitting diode, a xenon lamp, a mercury lamp, a halogen lamp, or the like. As long as the light includes the absorption peak wavelength of the optical device 1A, the light source 2 may emit light including a relatively wide wavelength range. The wavelength range of the light source 2 is determined to include the wavelength of the surface plasmon resonance in the optical device 1A. The light source 2 may be a constituent of the optical device 1A or may be an element outside the optical device 1A.

### Modifications

The optical device according to the present disclosure is described above based on the embodiment; however, the present disclosure is not limited to the above-described embodiment.

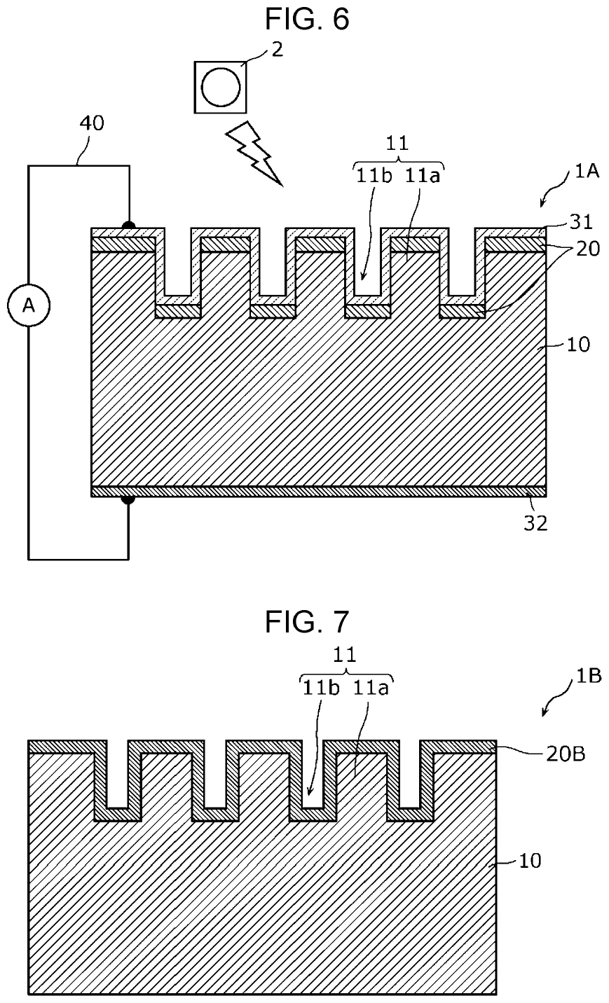

For example, in the above-described embodiment, the conductor 20 is formed on the top surface of the protruding portion 11a and the bottom surface of the depressed portion 11b in the uneven structure 11, and the conductor 20 is not formed on the side surface of the protruding portion 11a (that is, the side surface of the depressed portion 11b); however, the configuration is not limited thereto. Specifically, as illustrated in an optical device 1B in FIG. 7, a conductor 20B may be formed not only on the top surface of the protruding portion 11a and the bottom surface of the depressed portion 11b but also on the side surface of the protruding portion 11a (that is, the side surface of the depressed portion 11b). In FIG. 7, the conductor 20B covers the entire surface of the uneven structure 11 along the uneven shape of the uneven structure 11 without exposing the surface of the uneven structure 11. According to the optical device 1B illustrated in FIG. 7, it is possible to take out a current generated in the optical device 1B with no need of the first electrode layer 31 like the optical device 1A illustrated in FIG. 6. That is, in the optical device 1B illustrated in FIG. 7, the conductor 20B functions not only as a structure that induces surface plasmon resonance but also as an electrode to take out the induced hot electrons as a current.

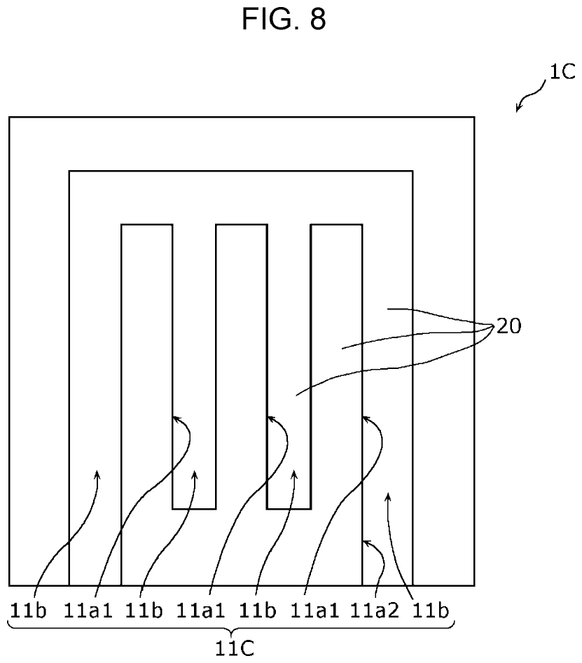

In the optical device 1 in the above-described embodiment, the multiple protruding portions 11a in the uneven structure 11 are arrayed in the form of a matrix when viewed from above; however, the configuration is not limited thereto. For example, like an optical device 1C illustrated in FIG. 8, an uneven structure 11C may be formed in the shape of a comb when viewed from above. Specifically, the uneven structure 11C includes, as protruding portions, multiple first protruding portions 11a1 in the form of stripes corresponding to comb teeth and second protruding portions 11a2 connecting end portions of the multiple first protruding portion 11a1. The multiple first protruding portions 11a1 extend in one direction and are parallel to each other. A portion between two adjacent first protruding portions 11a1 is the depressed portion 11b.

In the above-described embodiment, the conductor 20 is directly joined to both the top surface of the protruding portion 11a and bottom surface of the depressed portion 11b; however, the configuration is not limited thereto. For example, the conductor 20 may be directly joined to only either of the top surface of the protruding portion 11a and the bottom surface of the depressed portion 11b. That is, the conductor 20 may be joined by Schottky junction to either of the top surface of the protruding portion 11a and the bottom surface of the depressed portion 11b.

In the above-described embodiment, the uneven structure 11 includes the periodically formed multiple protruding portions 11a; however, the configuration is not limited thereto. The uneven structure 11 may include periodically formed multiple depressed portions 11b. That is, in the above-described optical device 1, the uneven structure 11 may have a shape in which the protruding portions 11a and the depressed portion 11b are in the reverse relationship. The uneven structure 11 may have a configuration in which both the multiple protruding portions 11a and depressed portions 11b are periodically formed.

In the above-described embodiment, the uneven structure 11 includes the protruding portion 11a and the depressed portion 11b in a single shape; however, the configuration is not limited thereto. The uneven structure 11 may include the protruding portion 11a and the depressed portion 11b having multiple widths, heights, and depths, and the shapes of the sections of the protruding portion 11a and the depressed portion 11b may be not only rectangular and may also be trapezoidal. In the above-described embodiment, the protruding portion 11a (the Si pillar) is formed in the shape of a square pillar when viewed from above; however, the configuration is not limited thereto, and the protruding portion 11a may be a quadrangular pillar, a polygonal pillar, or a column. In the above-described embodiment, the uneven structure 11 is formed in an array in a single cycle; however, the configuration is not limited thereto, and the uneven structure 11 may be in an array in multiple cycles or a random array. With such configurations, a broad absorption spectrum along with the surface plasmon resonance of multiple wavelengths is obtained, and it is useful for widening the bandwidth of a detection wavelength.

In the above-described embodiment, the light source 2 is arranged on the side on which the conductor 20 of the silicon substrate 10 is formed (the first principal surface side); however, the light source 2 may be arranged on the second principal surface side opposite to the first principal surface side. In this case, the light source 2 has near-infrared light that passes through the silicon substrate 10 or an electromagnetic wave that has a longer long wavelength than that of the near-infrared light, and also for the second electrode layer 32, a material (indium tin oxide (ITO) or the like) that is transparent to the electromagnetic wave from the light source 2 needs to be selected. With such a configuration, it is possible to induce highly efficiently surface plasmon resonance in the Schottky interface between the silicon substrate 10 and the conductor 20, and to reduce a loss during propagation of the induced hot electrons to the Schottky interface. Therefore, it is useful for improvement of the photoelectric conversion efficiency.

In addition, the present disclosure also includes a mode that is obtained by various modifications conceivable by those skilled in the art from the above-described embodiments and a mode that is implemented by properly combining the constituents and the functions in each embodiment without departing from the intent of the present disclosure.

The technique of the present disclosure can be used in a proper application in which the photoelectric conversion is performed. For example, the optical device according to the present disclosure can be used as a photodetection element or the like such as an image sensor.

What is claimed is:

1. An optical device, comprising:
a silicon substrate in which a plane direction of a crystal plane of a principal surface is a (111) plane, the principal surface having an uneven structure; and
a conductor that is joined to the silicon substrate by Schottky junction, wherein
the conductor is directly joined to a (111) plane of at least one of a protruding portion or a depressed portion in the uneven structure.

2. The optical device according to claim 1, wherein
the (111) plane of the protruding portion is a top surface of the protruding portion, and
the (111) plane of the depressed portion is a bottom surface of the depressed portion.

3. The optical device according to claim 2, wherein
the conductor is directly joined to both the top surface of the protruding portion and the bottom surface of the depressed portion.

4. The optical device according to claim 1, wherein
a side surface of the protruding portion or a side surface of the depressed portion has a portion with which the conductor is not in contact.

5. The optical device according to claim 1, wherein
the uneven structure has a characteristic of absorbing an electromagnetic wave through surface plasmon resonance.

6. The optical device according to claim 1, wherein
the conductor is an elemental metal or an alloy containing at least one selected from gold, silver, copper, palladium, and aluminum.

7. The optical device according to claim 1, wherein
the conductor is an oxide containing at least one selected from indium, tin, zinc, and cadmium.

8. The optical device according to claim 1, wherein
the conductor is a nitride containing at least one selected from titanium, zirconium, hafnium, vanadium, niobium, tantalum, molybdenum, and tungsten.

9. The optical device according to claim 1, wherein
the conductor is a laminated structure including at least two selected from (i) an elemental metal or an alloy containing at least one selected from gold, silver, copper, palladium, and aluminum, (ii) an oxide containing at least one selected from indium, tin, zinc, and cadmium, and (iii) a nitride containing at least one selected from titanium, zirconium, hafnium, vanadium, niobium, tantalum, molybdenum, and tungsten.

10. The optical device according to claim 1, further comprising
an electrode layer that covers the protruding portion, the depressed portion, and the conductor.
